(19) United States
(12) Patent Application Publication
(10) Pub. No.: US 2017/0271537 A1
(43) Pub. Date: Sep. 21, 2017

(54) FILTERLESS COLOR IMAGE SENSOR

(71) Applicant: KOREA INSTITUTE OF SCIENCE AND TECHNOLOGY, Seoul (KR)

(72) Inventors: Suyoun LEE, Seoul (KR); Byung-ki CHEONG, Seoul (KR); Seong Keun KIM, Seoul (KR); Do Kyung HWANG, Seoul (KR); Hyunsu JU, Seoul (KR); Young Tack LEE, Seoul (KR)

(73) Assignee: KOREA INSTITUTE OF SCIENCE AND TECHNOLOGY, Seoul (KR)

(21) Appl. No.: 15/444,806

(22) Filed: Feb. 28, 2017

(30) Foreign Application Priority Data
Mar. 18, 2016 (KR) 10-2016-0032520

(51) Int. Cl. H01L 31/032; H01L 31/109; H01L 31/112; H01L 27/146

(52) U.S. Cl. CPC H01L 31/0324; H01L 27/14645; H01L 31/109; H01L 31/1129

(57) ABSTRACT

Embodiments are directed to a chalcogenide material-based filterless color image sensor, which includes a substrate, a first chalcogenide material layer formed on a substrate for a first color, a second chalcogenide material layer formed on the first chalcogenide material layer for a second color, and a third chalcogenide material layer formed on the second chalcogenide material layer for a third color.

### CROSS-REFERENCE TO RELATED APPLICATION

This application claims the benefit under 35 USC 119(a) of Korean Patent Application No. 10-2016-0032520, filed on Mar. 18, 2016, and all the benefits accruing therefrom under 35 U.S.C. §119, the entire disclosure of which is incorporated herein by reference for all purposes.

### BACKGROUND

1. Field

The present disclosure relates to a filterless color image sensor, and more particularly, a color image sensor using a chalcogenide material layer, without using a color filter.

### DESCRIPTION ABOUT NATIONAL RESEARCH AND DEVELOPMENT SUPPORT

This study was supported by Project No. 1711030980 of Ministry of Science, ICT and Future Planning.

2. Description of the Related Art

FIGS. 1A and 1B show a color image sensor of the existing technique. FIG. 1A shows a filter-type color image sensor, and FIG. 1B shows a filterless laminated color image sensor.

The filter-type color image sensor depicted in FIG. 1A allows only light of a single color to pass among RGB lights by using a color filter, and the light is measured by a light receiving element therebelow. For example, a section of a pixel 10 is classified into a filter part 11 and a sensor part 12. Among RGB lights incident to the pixel 10, the filter 11 allows only a red (R) light to pass, and the sensor part 12 measures an intensity of the passing red light. At other pixels adjacent thereto, green (G) and blue (B) colors are detected in the same way, and they are combined to form a color image. However, in this filter-type color image sensor, since the intensity of light is attenuated at the color filter, the light receiving element should have a great area in order to make an electric signal over a certain level, and thus there is a limit in fabricating a high-resolution color image sensor by designing pixels in a small size.

As other problems of the filter-type color image sensor, a compound color is generated due to imperfect color selection of the color filter, and a deviated color is generated due to interference between color signals detected at adjacent cells. These problems become more severe as the element is designed with a smaller size, which gives a restraint on designing the color image sensor in a smaller size.

In order to solve the above problems, a laminated color image sensor without using a color filter as shown in FIG. 1B has been developed. This color image sensor is composed of light receiving elements laminated in a vertical direction. As an example, a color image sensor, in which photodiode-based light receiving elements made of silicon material are laminated vertically, uses a difference in the depth of penetration according to the wavelength of light. At an uppermost light receiving element (a third layer) where light arrives firstly, a blue (B) signal with a shortest wavelength is detected, and at an intermediate light receiving element (a second layer) where light arrives secondly, a green (G) signal is detected. Also, at a lowermost light receiving element (a first layer) where light arrives most lately, a red (R) signal with a longest wavelength is detected. Electric signals detected at every layer are combined to form a color image. However, a compound color is still present in this method, and the intensity of light transferred to the lower light receiving layer is insufficient. Due to these problems, a greater pixel size is demanded in comparison to the filter-type color image sensor described above, and thus this is not suitable for a smaller design.

As another example, a color image sensor configured by laminating organic materials with different bandgaps uses a difference in absorbed wavelengths depending on the bandgaps. However, the organic materials have very low photoelectric conversion efficiency and thermal instability and are thus not suitable for forming a laminated structure.

### RELATED LITERATURES

### Patent Literature

Korean Unexamined Patent Publication No. 10-2013-0039933 (Apr. 23, 2013)

### SUMMARY

In order to overcome the limit of resolution of a color image sensor, there is demanded a material which has high photoelectric conversion efficiency and allows easy formation of a laminated structure, and a filterless color image sensor using this material.

In one aspect, there is provided a chalcogenide material-based filterless color image sensor, comprising: a substrate; a first chalcogenide material layer formed on a substrate for a first color; a second chalcogenide material layer formed on the first chalcogenide material layer for a second color; and a third chalcogenide material layer formed on the second chalcogenide material layer for a third color.

The filterless color image sensor according to an embodiment may further comprise an image sensing circuit configured to measure a wavelength or intensity of incident light based on electric characteristic values respectively generated at the first chalcogenide material layer, the second chalcogenide material layer, and the third chalcogenide material layer.

In the filterless color image sensor according to an embodiment, at least one of the first chalcogenide material layer, the second chalcogenide material layer, and the third chalcogenide material layer may be two-dimensional material layers. Since the two-dimensional chalcogenide material has high transmittance due to a small thickness, the shortage of intensity of light at a lower layer may be solved. Also, due to very high photoelectric conversion efficiency, the problem described above may be suitably solved.

In the filterless color image sensor according to an embodiment, the first chalcogenide material layer may have a bandgap of 1.8 to 2.0 eV, the second chalcogenide material layer may have a bandgap of 2.2 to 2.4 eV, or the third chalcogenide material layer may have a bandgap of 2.5 to 2.7 eV.

In the filterless color image sensor according to an embodiment, the first chalcogenide material layer may include MoS₂ or WS₂.

In the filterless color image sensor according to an embodiment, the second chalcogenide material layer may include SnS₂.

In the filterless color image sensor according to an embodiment, the third chalcogenide material layer may include GaS or ZrS₂.

In the filterless color image sensor according to an embodiment, the first chalcogenide material layer, the second chalcogenide material layer, or the third chalcogenide material layer may be configured in a photodiode or phototransistor form.

In the filterless color image sensor according to an embodiment, the image sensing circuit may calculate a wavelength or intensity of light of the third color by using a third electric characteristic value generated at the third chalcogenide material layer. For example, the image sensing circuit may obtain a third color from a third electric characteristic value generated at the third chalcogenide material layer. In the filterless color image sensor according to an embodiment, the image sensing circuit may calculate a wavelength or intensity of light of the second color by using a second electric characteristic value generated at the second chalcogenide material layer and a third electric characteristic value generated at the third chalcogenide material layer.

For example, the image sensing circuit may obtain the second color by subtracting the third electric characteristic value generated at the third chalcogenide material layer from the second electric characteristic value generated at the second chalcogenide material layer. In the filterless color image sensor according to an embodiment, the image sensing circuit may calculate a wavelength or intensity of light of the first color by using a first electric characteristic value generated at the first chalcogenide material layer and a second electric characteristic value generated at the second chalcogenide material layer.

For example, the image sensing circuit may obtain the first color by subtracting the second electric characteristic value generated at the second chalcogenide material layer from the first electric characteristic value generated at the first chalcogenide material layer. In the filterless color image sensor according to an embodiment, the first color may be a red color, the second color may be a green color, and the third color may be a blue color.

According to an embodiment of the present disclosure, it is possible to provide a filterless color image sensor which overcomes the resolution limit of the existing technique.

### BRIEF DESCRIPTION OF THE DRAWINGS

The patent or application file contains a least one drawing executed in color. Copies of this patent or patent application publication with color drawing(s) will be provided by the Office upon request and payment of the necessary fee.

FIGS. 1A and 1B are cross-sectional views showing a color image sensor of the existing technique.

FIGS. 2 and 3 are cross-sectional views showing a chalcogenide material-based filterless color image sensor according to an embodiment of the present disclosure.

FIG. 4 shows an image reproduced using a filterless color image sensor 100 according to an embodiment of the present disclosure.

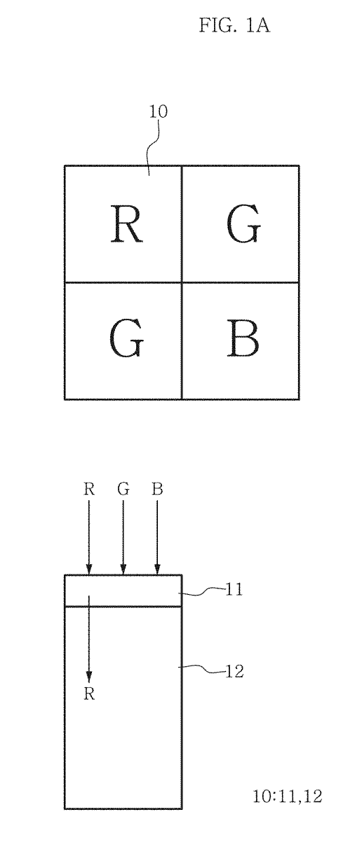

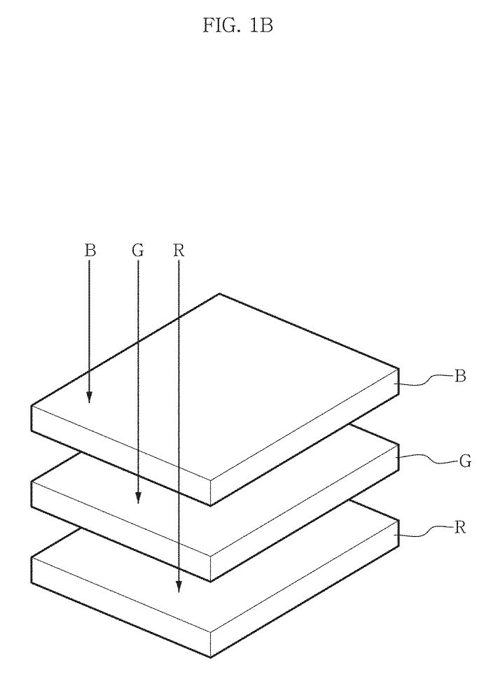

### DETAILED DESCRIPTION

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” and/or “comprising”, or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein. In the drawings, like reference numerals denote like elements. In the description, details of well-known features and techniques may be omitted to avoid unnecessarily obscuring the presented embodiments. The shape, size and regions, and the like, of the drawing may be exaggerated for clarity.

The following detailed description of the present disclosure refers to the accompanying drawings which show specific embodiments implemented by the present disclosure. These embodiments are described in detail so as to be easily implemented by those skilled in the art. It should be understood that various embodiments of the present disclosure are different from each other but not exclusive from each other. For example, specific shapes, structures and features written herein can be implemented in other embodiments without departing from the scope of the present disclosure. In addition, it should be understood that locations or arrangements of individual components in each embodiment may be changed without departing from the scope of the present disclosure. Therefore, the following detailed description is not directed to limiting the present disclosure, and the scope of the present disclosure is defined just with the appended claims along and their equivalents, if it is suitably explained. In the drawings, like reference numerals denote identical or similar functions in various aspects.

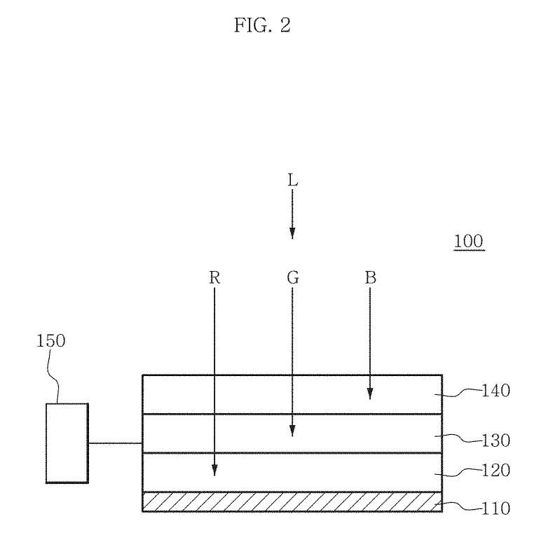

FIG. 2 is a cross-sectional view showing a chalcogenide material-based filterless color image sensor according to an embodiment of the present disclosure. Referring to FIG. 2, the chalcogenide material-based filterless color image sensor 100 includes a substrate 110, a first chalcogenide material layer 120 formed on the substrate 110 for a first color, a second chalcogenide material layer 130 formed on the first chalcogenide material layer 120 for a second color, and a third chalcogenide material layer 140 formed on the second chalcogenide material layer 130 for a third color. Here, the first to third colors may be colors with different wavelengths.

Light L incident to the filterless color image sensor 100 may pass through the first to third chalcogenide material layers 120-140. For example, the first to third chalcogenide material layers 120-140 may be configured to absorb RGB components of the incident light L, respectively.

Referring to FIG. 2, the first chalcogenide material layer may be associated with the first color, the second chalcogenide material layer may be associated with the second color, and the third chalcogenide material layer may be associated with the third color. Here, the first color may be a red color, the second color may be a green color, and the third color may be a blue color.

The first chalcogenide material layer 120 may have a bandgap of 1.8 to 2.0 eV. Preferably, the first chalcogenide material layer 120 may have a bandgap of about 1.9 eV.

In addition, the first chalcogenide material layer 120 may include MoS₂ or WS₂, without being limited thereto, and may include any chalcogenide material which may have a bandgap (1.8 to 2.0 eV) associated with the first color.

The second chalcogenide material layer 130 may have a bandgap of 2.2 to 2.4 eV. Preferably, the second chalcogenide material layer 130 may have a bandgap of about 2.3 eV.

In addition, the second chalcogenide material layer 130 may include SnS₂, without being limited thereto, and may include any chalcogenide material which may have a bandgap (2.2 to 2.4 eV) associated with the second color.

The third chalcogenide material layer 140 may have a bandgap of 2.5 to 2.7 eV. Preferably, the third chalcogenide material layer 140 may have a bandgap of about 2.6 eV.

In addition, the third chalcogenide material layer 140 may include GaS or ZrS₂, without being limited thereto, and may include any chalcogenide material which may have a bandgap (2.5 to 2.7 eV) associated with the third color.

The chalcogenide material layers described in the present disclosure may include a compound containing at least one element selected from sulfur (S), selenium (Se), and tellurium (Te). As a photoelectric material, the chalcogenide material has greater photoelectric conversion efficiency in comparison to silicon and also allows making a junction with similar characteristics to the p-n characteristics when contacting metal. Since the p-n characteristics may be implemented just with a contact to metal, a complicated process for making a p-n junction with silicon may be excluded, thereby lowering the process costs. In an embodiment, the chalcogenide material may be a multi-component material having at least two components, prepared by bonding at least one element selected from transition metal elements belonging to 3 to 12 groups of the periodic table and at least one element selected from S, Se, and Te, which are chalcogen elements. In another embodiment, the chalcogenide material may be a multi-component material having at least two components, prepared by bonding at least one element selected from Al, Ga, Si, Ge, P, As, and Sb, which belong to 13 to 15 groups of the periodic table and at least one element selected from S, Se, and Te, which are chalcogen elements. In an embodiment, the chalcogenide material layers 120-140 may be respectively deposited on read-out circuits 121-141 by means of various thin film deposition methods such as sputtering, CVD, and evaporation.

Also, in an embodiment, at least one of the first chalcogenide material layer 120, the second chalcogenide material layer 130, and the first chalcogenide material layer 140 may be a two-dimensional material layer. By using the two-dimensional chalcogenide material layer, the photoelectric conversion efficiency may be improved greatly, and the shortage of intensity of light at a lower light receiving layer may be solved by means of high transmittance obtained by a small thickness.

In addition, a transparent electrode (not shown) may also be formed on the third chalcogenide material layer 140.

Moreover, the first chalcogenide material layer, the second chalcogenide material layer, or the third chalcogenide material layer may be configured in a photodiode or phototransistor form.

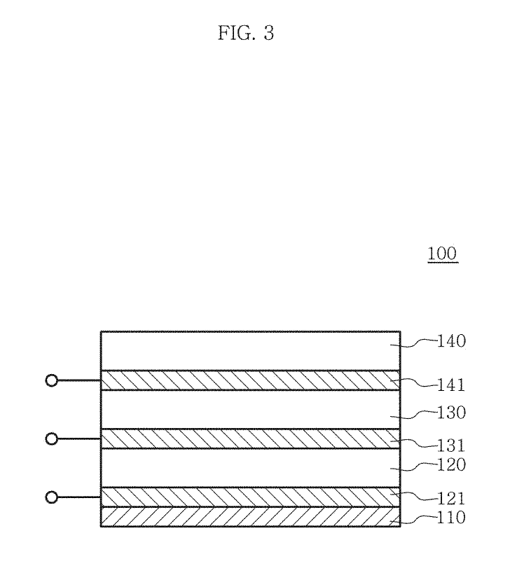

In an embodiment, the filterless color image sensor 100 may further include an image sensing circuit 150. The image sensing circuit 150 may be electrically connected to the first to third chalcogenide material layers 120-140. For the connection between the image sensing circuit 150 and the first to third chalcogenide material layers 120-140, the first to third chalcogenide material layers 120-140 may respectively include the read-out circuits 121, 131, 141, as shown in FIG. 3. In FIG. 3, the read-out circuits 121-141 are depicted as having the same area as the chalcogenide material layer, but in another embodiment, the read-out circuits may respectively have a different area from the chalcogenide material layer.

The image sensing circuit 150 may measure a wavelength or intensity of incident light, based on electric characteristic values respectively generated at the first chalcogenide material layer, the second chalcogenide material layer, and the third chalcogenide material layer. Here, the electric characteristic value may be a voltage value or a current value, without being limited thereto.

For example, the image sensing circuit 150 may obtain an intensity of the first color (for example, a red color) based on the electric characteristic value measured at the first chalcogenide material layer 120, obtain an intensity of the second color (for example, a green color) based on the electric characteristic value measured at the second chalcogenide material layer 130, obtain an intensity of the third color (for example, a blue color) based on the electric characteristic value measured at the third chalcogenide material layer 140, and determine a color and intensity of the incident light based on the intensities of the first to third colors.

Also, in an embodiment, the image sensing circuit 150 may calculate a wavelength or intensity of light of the second color by using the second electric characteristic value generated at the second chalcogenide material layer and the third electric characteristic value generated at the third chalcogenide material layer. For example, the image sensing circuit 150 may calculate a wavelength or intensity of light of the second color by subtracting the third electric characteristic value generated at the third chalcogenide material layer from the second electric characteristic value generated at the second chalcogenide material layer.

Similarly, in an embodiment, the image sensing circuit 150 may calculate a wavelength or intensity of light of the first color by using the first electric characteristic value generated at the first chalcogenide material layer and the second electric characteristic value generated at the second chalcogenide material layer. For example, the image sensing circuit 150 may calculate a wavelength or intensity of light of the first color by subtracting the second electric characteristic value generated at the second chalcogenide material layer from the first electric characteristic value generated at the first chalcogenide material layer.

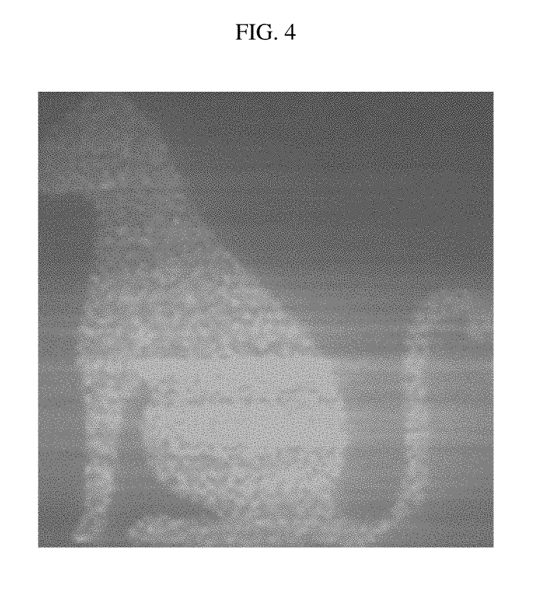

FIG. 4 shows an image reproduced using the filterless color image sensor 100 according to an embodiment of the present disclosure. The cat image of FIG. 4 was obtained using a MoS₂ single-crystal material to sense a green component. FIG. 4 shows that it is possible to extract a color element of a specific wavelength by using a chalcogenide material layer of a specific bandgap. From the experimental results, it may be understood that the filterless color image sensor according to an embodiment of the present disclosure is capable of reproducing actual colors very accurately by using three chalcogenide material layers.

While the exemplary embodiments have been shown and described, it will be understood by those skilled in the art that various changes in form and details may be made thereto without departing from the spirit and scope of the present disclosure as defined by the appended claims. In addition, many modifications can be made to adapt a particular situation or material to the teachings of the present disclosure without departing from the essential scope thereof.

Therefore, it is intended that the present disclosure not be limited to the particular exemplary embodiments disclosed as the best mode contemplated for carrying out the present disclosure, but that the present disclosure will include all embodiments falling within the scope of the appended claims.

### REFERENCE SYMBOLS

100: filterless color image sensor
110: substrate
120: first chalcogenide material layer
130: second chalcogenide material layer
140: third chalcogenide material layer
150: image sensing circuit

What is claimed is:

1. A chalcogenide material-based filterless color image sensor, comprising:
a substrate;
a first chalcogenide material layer formed on a substrate for a first color;
a second chalcogenide material layer formed on the first chalcogenide material layer for a second color; and
a third chalcogenide material layer formed on the second chalcogenide material layer for a third color.

2. The chalcogenide material-based filterless color image sensor according to claim 1, further comprising:
an image sensing circuit configured to measure a wavelength or intensity of incident light based on electric characteristic values respectively generated at the first chalcogenide material layer, the second chalcogenide material layer, and the third chalcogenide material layer.

3. The chalcogenide material-based filterless color image sensor according to claim 1,
wherein at least one of the first chalcogenide material layer, the second chalcogenide material layer, and the third chalcogenide material layer are two-dimensional material layers.

4. The chalcogenide material-based filterless color image sensor according to claim 1,
wherein the first chalcogenide material layer has a bandgap of 1.8 to 2.0 eV,
the second chalcogenide material layer has a bandgap of 2.2 to 2.4 eV, or
the third chalcogenide material layer has a bandgap of 2.5 to 2.7 eV.

5. The chalcogenide material-based filterless color image sensor according to claim 1,
wherein the first chalcogenide material layer includes MoS₂ or WS₂.

6. The chalcogenide material-based filterless color image sensor according to claim 1,
wherein the second chalcogenide material layer includes SnS₂.

7. The chalcogenide material-based filterless color image sensor according to claim 1,
wherein the third chalcogenide material layer includes GaS or ZrS₂.

8. The chalcogenide material-based filterless color image sensor according to claim 1,
wherein the first chalcogenide material layer, the second chalcogenide material layer, or the third chalcogenide material layer is configured in a photodiode or phototransistor form.

9. The chalcogenide material-based filterless color image sensor according to claim 2,
wherein the image sensing circuit calculates a wavelength or intensity of light of the second color by using a second electric characteristic value generated at the second chalcogenide material layer and a third electric characteristic value generated at the third chalcogenide material layer.

10. The chalcogenide material-based filterless color image sensor according to claim 2,
wherein the image sensing circuit calculates a wavelength or intensity of light of the first color by using a first electric characteristic value generated at the first chalcogenide material layer and a second electric characteristic value generated at the second chalcogenide material layer.

11. The chalcogenide material-based filterless color image sensor according to claim 2,
wherein the image sensing circuit calculates a wavelength or intensity of light of the third color by using a third electric characteristic value generated at the third chalcogenide material layer.

12. The chalcogenide material-based filterless color image sensor according to claim 1,
wherein the first color is a red color, the second color is a green color, and the third color is a blue color.
